(19) United States
(12) Patent Application Publication
(10) Pub. No.: US 2026/0136636 A1
(43) Pub. Date: May 14, 2026

(54) SILICON CAPACITOR SEMICONDUCTOR DEVICE AND METHOD FOR MANUFACTURING THE SAME

(71) Applicant: DB HiTek Co., Ltd., Seoul (KR)

(72) Inventor: Chang Hun Han, Icheon-si (KR)

(21) Appl. No.: 19/028,648

(22) Filed: Jan. 17, 2025

(30) Foreign Application Priority Data
Nov. 13, 2024 (KR) 10-2024-0160874

(51) Int. Cl. H10D 80/20; H10D 1/00; H10D 1/68

(52) U.S. Cl. CPC H10D 80/215; H10D 1/042; H10D 1/716

(57) ABSTRACT

A silicon capacitor semiconductor device is proposed. The silicon capacitor may include a first substrate, an epitaxial layer grown from the same material as that of the first substrate, and a first buffer layer formed along a profile of a first trench formed in the first substrate. The silicon capacitor may also include a first capacitor structure on the first buffer layer, a first interlayer insulating layer on the first capacitor structure, and a second buffer layer formed along a profile of a second trench formed in the epitaxial layer. The silicon capacitor may further include a second capacitor structure on the second buffer layer and a second interlayer insulating layer between the first interlayer insulating layer and the second capacitor structure.

### CROSS-REFERENCE TO RELATED APPLICATION

This application claims priority to and the benefit of Korean Patent Application No. 10-2024-0160874 filed on Nov. 13, 2024 in the Korean Intellectual Property Office, the entire contents of which are incorporated herein by reference.

### BACKGROUND

### Technical Field

The present disclosure relates to a silicone capacitor semiconductor device and a method for manufacturing the same.

### Description of Related Technology

The content described here merely provides background information for this embodiment and does not constitute prior art.

The implementation of high-capacity capacitors can be an essential technical requirement in miniaturized electronic devices, and various methods for increasing capacitance have been continuously researched. To meet these technical requirements, a wafer-based deep trench capacitor (DTC) structure can be introduced. Conventionally, methods for increasing capacitance primarily used a single wafer, and attempts were made to increase capacitance by forming deep trenches on the wafer surface and placing electrodes and insulating layers. However, the method of increasing capacitance using only a single wafer may have limitations, especially in satisfying the high capacitance levels required for miniaturized electronic devices.

### SUMMARY

One aspect is a silicon capacitor semiconductor device and a method for manufacturing the same.

The aspects of the present disclosure are not limited to those disclosed herein, and other aspects and advantages not mentioned can be understood through the following description and will be more clearly understood through the embodiments of the present disclosure. Furthermore, the aspects and advantages of the present disclosure can be realized through the means and combinations of those means presented in the claims.

Some embodiments of the silicon capacitor semiconductor device and the method for manufacturing the same according to the present disclosure have the advantage of enabling miniaturization of semiconductor chips by implementing capacitors with high capacitance per unit area.

Further, some embodiments of the silicon capacitor semiconductor device and the method for manufacturing the same according to the present disclosure bond silicon capacitor semiconductor devices through separate processes to prevent the manufacturing process of one silicon capacitor semiconductor device from negatively affecting the manufacturing quality of other devices, thus reducing the defect rate significantly.

In addition to the aforementioned, the specific effects of the disclosure will be described in detail while explaining the specific aspects of implementing the disclosure.

The aspects of the present disclosure are not limited to those mentioned above, and other objects and advantages not mentioned can be understood through the following description and will be more clearly understood through the embodiments of the present disclosure. Furthermore, the objects and advantages of the present disclosure can be realized through the means and combinations of those means presented in the claims.

Another aspect is a silicon capacitor semiconductor device comprising: a first substrate; an epitaxial layer grown from the same material as that of the first substrate; a first buffer layer formed along a profile of a first trench formed in the first substrate; a first capacitor structure on the first buffer layer; a first interlayer insulating layer on the first capacitor structure; a second buffer layer formed along a profile of a second trench formed in the epitaxial layer; a second capacitor structure on the second buffer layer and a second interlayer insulating layer between the first interlayer insulating layer and the second capacitor structure.

Further, wherein the first capacitor structure comprises a first-1 electrode, a first dielectric layer on the first-1 electrode, and a first-2 electrode on the first dielectric layer and the second capacitor structure comprises a second-1 electrode, a second dielectric layer on the second-1 electrode, and a second-2 electrode on the second dielectric layer.

Further, the silicon capacitor semiconductor device further comprises: a first-1 electrode pad structure connected to the first-1 electrode and passing through at least a portion of the first interlayer insulating layer; a first-2 electrode pad structure connected to the first-2 electrode and passing through at least a portion of the first interlayer insulating layer; a second-1 electrode pad structure connected to the second-1 electrode and passing through at least a portion of the second interlayer insulating layer and a second-2 electrode pad structure connected to the second-2 electrode and passing through at least a portion of the second interlayer insulating layer.

Further, the silicon capacitor semiconductor device further comprises a contact layer passing through at least a portion of the epitaxial layer, the second buffer layer, the second interlayer insulating layer, and the first interlayer insulating layer.

Further, the silicon capacitor semiconductor device further comprises: a third interlayer insulating layer formed between the contact layer and the epitaxial layer and a passivation layer on the contact layer.

Further, wherein the contact layer comprises multiple layers.

Further, wherein the first interlayer insulating layer comprises a first-1 interlayer insulating layer and a first-2 interlayer insulating layer on the first-1 interlayer insulating layer; the second interlayer insulating layer comprises a second-1 interlayer insulating layer and a second-2 interlayer insulating layer on the second-1 interlayer insulating layer and the first-2 interlayer insulating layer and the second-2 interlayer insulating layer are made of the same material.

Further, wherein the first-2 interlayer insulating layer and the second-2 interlayer insulating layer are in direct contact with each other.

Further, wherein the first and second buffer layers each comprise at least one of silicon dioxide (SiO2), phosphosilicate glass (PSG), borosilicate glass (BSG), borosilicate phosphosilicate glass (BPSG), silicon nitride (Si3N4), silicon oxynitride (SiON), and hafnium oxide (HfO2).

Further, wherein the first and second interlayer insulating layers each comprise at least one of silicon oxide (SiO2), silicon nitride (Si3N4), polyimide, silicon carbide (SiC), phosphosilicate glass (PSG), borosilicate glass (BSG), hafnium oxide (HfO2), and silicon oxynitride (SiON).

Another aspect is a method for manufacturing a silicon capacitor semiconductor device that comprises: forming a first trench in a first substrate, forming a first buffer layer, a first-1 electrode, a first dielectric layer, and a first-2 electrode on at least a portion of the first trench, forming a first-1 interlayer insulating layer on the first-2 electrode, forming a first-1 electrode pad structure and a first-2 electrode pad structure that penetrate the first-1 interlayer insulating layer, and forming a first-2 interlayer insulating layer covering the first-1 electrode pad structure and the first-2 electrode pad structure; forming an epitaxial layer on a second substrate different from the first substrate, the epitaxial layer being made of the same material as the second substrate, forming a second trench in the epitaxial layer, forming a second buffer layer, a second-1 electrode, a second dielectric layer, and a second-2 electrode on at least a portion of the second trench, forming a second-1 interlayer insulating layer on the second-2 electrode, forming a second-1 electrode pad structure and a second-2 electrode pad structure that penetrate the second-1 interlayer insulating layer, and forming a second-2 interlayer insulating layer covering the second-1 electrode pad structure and the second-2 electrode pad structure; bonding the first-2 interlayer insulating layer and the second-2 interlayer insulating layer using at least one of thermal compression bonding, surface activation bonding, chemical mechanical polishing (CMP) bonding, direct wafer bonding, or annealing bonding and removing the second substrate using a selectivity ratio between the second substrate and the epitaxial layer.

Further, the method for manufacturing the silicon capacitor semiconductor device further comprises forming a contact structure connected to the first-1 electrode pad structure, the first-2 electrode pad structure, the second-1 electrode pad structure, and the second-2 electrode pad structure.

Further, the method for manufacturing the silicon capacitor semiconductor device further comprises conformally forming a third interlayer insulating layer on the epitaxial layer.

Further, wherein the forming of the contact structure comprises: removing at least a portion of the epitaxial layer, the second buffer layer, and the second-1 interlayer insulating layer to expose the second-1 electrode pad structure and the second-2 electrode pad structure; removing at least a portion of the epitaxial layer, the second buffer layer, the second-1 interlayer insulating layer, the second-2 interlayer insulating layer, and the first-2 interlayer insulating layer to expose the first-1 electrode pad structure and the first-2 electrode pad structure and forming the contact structure to contact the first-1 electrode pad structure, the first-2 electrode pad structure, the second-1 electrode pad structure, and the second-2 electrode pad structure.

Another aspect is a silicon capacitor semiconductor device that comprises: a first substrate with a first trench; a first capacitor structure on the first trench, the first capacitor structure including a first-1 electrode layer on the first trench, a first-1 dielectric layer on the first-1 electrode layer, a first-2 electrode layer on the first-1 dielectric layer, a first-2 dielectric layer on the first-2 electrode layer, and a first-3 electrode layer on the first-2 dielectric layer; an epitaxial layer with a second trench, the epitaxial layer being formed by an epitaxy process; a second capacitor structure on the second trench, the second capacitor structure including a second-1 electrode layer on the second trench, a second-1 dielectric layer on the second-1 electrode layer, a second-2 electrode layer on the second-1 dielectric layer, a second-2 dielectric layer on the second-2 electrode layer, and a second-3 electrode layer on the second-2 dielectric layer; a first interlayer insulating layer on the first capacitor structure and a second interlayer insulating layer on the second capacitor structure, wherein at least portions of the first interlayer insulating layer and the second interlayer insulating layer are in direct contact with each other.

Further, the silicon capacitor semiconductor device according to claim 15, further comprises: a first electrode pad structure connected to the first capacitor structure and a second electrode pad structure connected to the second capacitor structure.

Further, the silicon capacitor semiconductor device further comprises: a contact structure that penetrates at least a portion of the first interlayer insulating layer and the second interlayer insulating layer to be connected to the first electrode pad structure and penetrates at least a portion of the second interlayer insulating film to be connected to the second electrode pad structure.

Further, the contact structure comprises a first contact layer directly contacting the first electrode pad structure and the second electrode pad structure and a passivation layer on the first contact layer.

Further, the contact structure comprises a first contact layer directly contacting the first electrode pad structure and the second electrode pad structure, a second contact layer on the first contact layer, the second contact layer being made of a different material or having a different composition ratio than the first contact layer, and a passivation layer on the second contact layer.

Further, the first interlayer insulating layer comprises a first-1 interlayer insulating layer and a first-2 interlayer insulating layer on the first-1 interlayer insulating layer, the second interlayer insulating layer comprises a second-1 interlayer insulating layer and a second-2 interlayer insulating layer on the second-1 interlayer insulating layer and the first-2 interlayer insulating layer and the second-2 interlayer insulating layer are made of the same material.

### BRIEF DESCRIPTION OF THE DRAWINGS

FIG. 1 is a cross-sectional view illustrating a silicon capacitor semiconductor device according to some embodiments of the present disclosure.

FIG. 2A depicts the manufacturing process of the second deep trench capacitor DTC_2 according to some embodiments of the disclosure.

FIG. 2B depicts the manufacturing process of the first deep trench capacitor DTC_1 according to some embodiments of the disclosure.

FIG. 3A depicts the manufacturing process of the second deep trench capacitor DTC_2 according to some embodiments of the disclosure.

FIG. 3B depicts the manufacturing process of the first deep trench capacitor DTC_1 according to some embodiments of the disclosure.

FIG. 4 depicts the first deep trench capacitor DTC_1 and the second deep trench capacitor DTC_2 bonded together according to some embodiments of the disclosure.

FIG. 5 is a cross-sectional view illustrating the state after bonding the first deep trench capacitor DTC_1 and the second deep trench capacitor DTC_2, with the second substrate removed according to some embodiments of the disclosure.

FIG. 6 is a cross-sectional view illustrating the third interlayer insulating layer conformally formed on the epitaxial layer according to some embodiments of the disclosure.

FIG. 7 is a cross-sectional view illustrating, for the sake of explanation, the overlapping area defined as a first region R1, and the overlapping area defined as a second region R2 according to some embodiments of the disclosure.

FIG. 8 is a cross-sectional view illustrating the fourth interlayer insulating layer conformally formed on the third interlayer insulating layer, the third trench T3, and the fourth trench T4 according to some embodiments of the disclosure.

FIG. 9 is a cross-sectional view illustrating a fifth trench T5 formed in the second region R2 according to some embodiments of the disclosure.

FIG. 10 is a cross-sectional view illustrating a sixth trench T6 formed in the first region R1 according to some embodiments of the disclosure.

FIG. 11 is a cross-sectional view illustrating a first contact layer formed to contact the first-1 electrode pad structure, the first-2 electrode pad structure, the second-1 electrode pad structure, and the fourth electrode pad structure according to some embodiments of the disclosure.

FIG. 12 illustrates a cross-sectional view of a silicon capacitor semiconductor device according to other embodiments of the present disclosure.

FIG. 13 illustrates a cross-sectional view of a silicon capacitor semiconductor device according to other embodiments of the present disclosure.

### DETAILED DESCRIPTION

In the single wafer-based capacitor implementation, there are limitations in maximizing capacitance per unit area because of the restricted area of each wafer. Further, the single wafer structure can have limitations in the stability of electrical characteristics and heat dissipation due to physical constraints, which can negatively affect the reliability and performance of the electronic device.

Along with this, as through-silicon via (TSV) technology has developed, methods of improving the efficiency of power and signal transmission through electrical connections between wafers have been introduced. The TSV technology has the advantage of greatly improving electrical performance and assisting with heat dissipation by connecting wafers, but the design and manufacturing process may become more complex when combined with high-density capacitor structures. The method of wafer bonding using TSV requires considering both electrical connections and capacitance increase simultaneously, which can increase the complexity and cost of the manufacturing process. This complexity can increase the difficulty of design and production, leading to higher costs and limits to mass commercialization.

Therefore, the inability to combine the existing single-wafer-based deep trench capacitor structure with TSV connection technology may lead to difficulties in simultaneously satisfying high capacitance and electrical performance, especially in meeting the requirements for implementing high-density capacitors in miniaturized electronic devices. To address this problem, a new high-capacity capacitor design that combines wafer multilayer structures with through-silicon vias may be required.

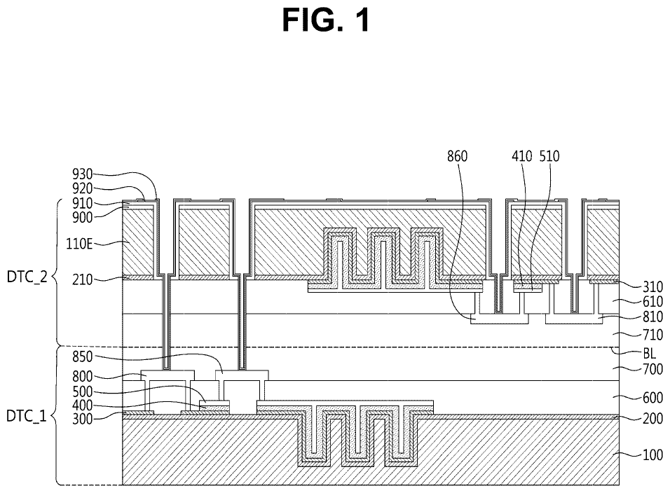

FIG. 1 is a cross-sectional view illustrating a silicon capacitor semiconductor device according to some embodiments of the present disclosure.

Referring to FIG. 1, the silicon capacitor semiconductor device according to some embodiments of the present disclosure may include a first deep trench capacitor DTC_1, a second deep trench capacitor DTC_2, a third interlayer insulating layer 900, a fourth interlayer insulating layer 910, a first contact layer 920, and a passivation layer 930.

The first deep trench capacitor DTC_1 may include a first substrate 100, a first buffer layer 200, a first-1 electrode 300, a first dielectric layer 400, a first-2 electrode 500, a first-1 interlayer insulating layer 600, a first-1 electrode pad structure 800, a first-2 electrode pad structure 850, and a first-2 interlayer insulating layer 700.

In some embodiments, the first substrate 100 may be a silicon (Si) substrate. However, this is merely exemplary, and the embodiments are not limited to this. For example, the first substrate 100 may be formed using at least one of gallium arsenide (GaAs), sapphire (Al₂O₃), silicon carbide (SiC), indium phosphide (InP), polymer, and organic substrates. However, for convenience of explanation, the first substrate 100 will be described as being composed of silicon.

The first buffer layer 200 may be formed on the first substrate 100. More specifically, the first buffer layer 200 may be formed conformally following the surface shape of the first substrate 100. In some embodiments, the first substrate 100 may have one or more trenches formed therein, and the first buffer layer 200 may be formed conformally along the top surface of the first substrate 100 and the trenches formed on the first substrate 100.

The first buffer layer 200 is formed on the first substrate 100 and may function to relieve stress on the first substrate 100 and act as an insulating layer. The first substrate 100 may deform by stress due to external conditions such as heat in subsequent processes. Even if the first substrate 100 deforms, the first buffer layer 200 serves to buffer these stresses applied to other structures formed on the first buffer layer 200. Furthermore, the first buffer layer 200 provides electrical insulation between the first substrate 100 and structures formed on the first buffer layer 200, preventing leakage current and enhancing the stability of the capacitor structure.

The first buffer layer 200 may, for example, include at least one high-k dielectric material among silicon dioxide (SiO₂), phosphosilicate glass (PSG), borosilicate glass (BSG), borosilicate phosphosilicate glass (BPSG), silicon nitride (Si₃N₄), silicon oxynitride (SiON), and hafnium oxide (HfO₂). However, this is merely exemplary, and the embodiments are not limited to this.

The first-1 electrode 300 may be formed on the first buffer layer 200. More specifically, the first-1 electrode 300 may be formed conformally along at least a portion of the surface shape of the first buffer layer 200.

The first dielectric layer 400 may be formed on the first-1 electrode 300. More specifically, the first dielectric layer 400 may be formed conformally along at least a portion of the surface shape of the first-1 electrode 300.

The first-2 electrode 500 may be formed on the first dielectric layer 400. More specifically, the first-2 electrode 500 may be formed conformally along at least a portion of the surface shape of the first dielectric layer 400.

The first-1 electrode 300 and the first-2 electrode 500 may be positioned opposite each other with the first dielectric layer 400 therebetween. The first-1 electrode 300 and the first-2 electrode 500 may form an electric field through opposite-polarity charges. For example, when the first-1 electrode 300 is applied with a negative charge, the first-2 electrode 500 may be applied with a positive charge, creating an electric field between the first-1 electrode 300 and the first-2 electrode 500.

The first-1 electrode 300 and the first-2 electrode 500 may include at least one material among aluminum (AI), copper (Cu), silver (Ag), gold (Au), nickel (Ni), tungsten alloy (W), titanium-nickel alloy (TiNi), chromium-copper alloy (CrCu), indium tin oxide (ITO), ruthenium dioxide (RuO₂), and iridium oxide (IrO₂). However, this is merely exemplary, and the embodiments are not limited to this.

The first dielectric layer 400 is positioned between the first-1 electrode 300 and the first-2 electrode 500 and, while not directly storing charge, helps to form an electric field between the first-1 electrode 300 and the first-2 electrode 500, thus assisting in efficient charge accumulation. The higher the dielectric constant of the first dielectric layer 400, the more charge can be stored. Further, the first dielectric layer 400 electrically insulates the first-1 electrode 300 and the first-2 electrode 500, preventing leakage current.

The first dielectric layer 400 may include at least one material among silicon dioxide (SiO₂), fluorinated silicon dioxide (FSG), polyimide, aluminum oxide (Al₂O₃), silicon nitride (Si₃N₄), silicon oxynitride (SiON), hafnium oxide (HfO₂), zirconium oxide (ZrO₂), titanium dioxide (TiO₂), tantalum oxide (Ta₂O₅), lanthanum oxide (La₂O₃), and yttrium oxide (Y₂O₃). However, this is merely exemplary, and the embodiments are not limited to this.

The first-1 interlayer insulating layer 600 may be formed on the first substrate 100, the first buffer layer 200, the first-1 electrode 300, the first dielectric layer 400, and the first-2 electrode 500. The first-1 interlayer insulating layer 600 may be formed to cover the first substrate 100, the first buffer layer 200, the first-1 electrode 300, the first dielectric layer 400, and the first-2 electrode 500. The first-1 interlayer insulating layer 600 can provide electrical insulation to prevent interference between the electrical structures arranged above and below. Further, when electrical signals operate at high frequencies, the first-1 interlayer insulating layer 600 may be used to prevent signal interference between adjacent layers and may be necessary to ensure structural stability and mechanical protection.

The first-1 electrode pad structure 800 and the first-2 electrode pad structure 850 may be formed on the first-1 interlayer insulating layer 600 and may penetrate through the first-1 interlayer insulating layer 600. The first-1 electrode pad structure 800 may be connected to the first-1 electrode 300, and the first-2 electrode pad structure 850 may be connected to the first-2 electrode 500. The first-1 electrode pad structure 800 and the first-2 electrode pad structure 850 may be later connected to a contact structure, distributing electricity evenly to the first-1 electrode 300 and the first-2 electrode 500.

The first-1 electrode pad structure 800 and the first-2 electrode pad structure 850 may include at least one material among copper (Cu), gold (Au), aluminum (AI), nickel (Ni), palladium (Pd), silver (Ag), titanium (Ti), chromium (Cr), nickel-gold plating (Ni—Au Plating), copper-nickel-palladium plating (Cu—Ni—Pd Plating), and silver-palladium plating (Ag—Pd Plating). However, this is merely exemplary, and the embodiments are not limited to this.

The first-2 interlayer insulating layer 700 may be formed on the first-1 interlayer insulating layer 600, the first-1 electrode pad structure 800, and the first-2 electrode pad structure 850. The first-2 interlayer insulating layer 700 may be a portion that is connected to the second deep trench capacitor DTC_2.

The first-1 interlayer insulating layer 600 and the first-2 interlayer insulating layer 700 may include at least one material among silicon oxide (SiO₂), silicon nitride (Si₃N₄), polyimide, silicon carbide (SiC), low-k dielectric materials, phosphosilicate glass (PSG), borosilicate glass (BSG), hafnium oxide (HfO₂), and silicon oxynitride (SiON). However, this is merely exemplary, and the embodiments are not limited to this.

The second deep trench capacitor DTC_2 may include an epitaxial layer 110E, a second buffer layer 210, a second-1 electrode 310, a second dielectric layer 410, a second-2 electrode 510, a second-1 interlayer insulating layer 610, a second-1 electrode pad structure 810, and a second-2 interlayer insulating layer 710.

In some embodiments, the epitaxial layer 110E may be a silicon (Si) layer grown by epitaxy. However, this is merely exemplary, and the embodiments are not limited to this. The epitaxial layer 110E may contain the same material as the second substrate 110, and may represent a material layer grown by epitaxy. In some embodiments, the second substrate 110 and the epitaxial layer 110E, which are composed of the same material, may differ in terms of the material's purity. For example, the silicon in the second substrate 110 may have a higher purity than that of the epitaxial layer 110E. Due to this difference in purity, the second substrate 110 can be more easily removed during etching and planarization processes. Further detailed explanation will be provided later.

The second buffer layer 210 may be formed on the epitaxial layer 110E. More specifically, the second buffer layer 210 may be formed conformally along the surface shape of the epitaxial layer 110E. In some embodiments, one or more trenches may be formed on the epitaxial layer 110E, and the second buffer layer 210 may be formed conformally along the top surface of the epitaxial layer 110E and the trenches formed in the epitaxial layer 110E.

The second buffer layer 210, formed on the epitaxial layer 110E, may relieve stress on the epitaxial layer 110E and function as an insulating layer. In other words, the second buffer layer 210 can serve to buffer the epitaxial layer 110E against deformation caused by external factors while simultaneously preventing leakage current, thereby enhancing the stability of the capacitor structure.

The second buffer layer 210 may include, for example, at least one high-k dielectric material among silicon dioxide (SiO₂), phosphosilicate glass (PSG), borosilicate glass (BSG), borosilicate phosphosilicate glass (BPSG), silicon nitride (Si₃N₄), silicon oxynitride (SiON), and hafnium oxide (HfO₂). However, this is merely exemplary, and the embodiments are not limited to this.

The second-1 electrode 310 may be formed on the second buffer layer 210. More specifically, the second-1 electrode 310 may be formed conformally along at least a portion of the surface shape of the second buffer layer 210. The second dielectric layer 410 may be formed on the second-1 electrode 310. More specifically, the second dielectric layer 410 may be formed conformally along at least a portion of the surface shape of the second-1 electrode 310. The second-2 electrode 510 may be formed on the second dielectric layer 410. More specifically, the second-2 electrode 510 may be formed conformally along at least a portion of the surface shape of the second dielectric layer 410.

The second-1 electrode 310 and the second-2 electrode 510 may be positioned opposite each other with the second dielectric layer 410 therebetween. In other words, the second dielectric layer 410 may be located between the second-1 electrode 310 and the second-2 electrode 510.

The second-1 electrode 310 and the second-2 electrode 510 may form an electric field through opposite-polarity charges. The second-1 electrode 310 and the second-2 electrode 510 may include at least one material among aluminum (AI), copper (Cu), silver (Ag), gold (Au), nickel (Ni), tungsten alloy (W), titanium-nickel alloy (TiNi), chromium-copper alloy (CrCu), indium tin oxide (ITO), ruthenium dioxide (RuO₂), and iridium oxide (IrO₂). However, this is merely exemplary, and the embodiments are not limited to this.

The second dielectric layer 410 may include at least one material among silicon oxide (SiO₂), fluorinated silicon dioxide (FSG), polyimide, aluminum oxide (Al₂O₃), silicon nitride (Si₃N₄), silicon oxynitride (SiON), hafnium oxide (HfO₂), zirconium oxide (ZrO₂), titanium oxide (TiO₂), tantalum oxide (Ta₂O₅), lanthanum oxide (La₂O₃), and yttrium oxide (Y₂O₃). However, this is merely exemplary, and the embodiments are not limited to this.

The second-1 interlayer insulating layer 610 may be formed on the epitaxial layer 110E, the second buffer layer 210, the second-1 electrode 310, the second dielectric layer 410, and the second-2 electrode 510. The second-1 interlayer insulating layer 610 may be formed to cover the epitaxial layer 110E, the second buffer layer 210, the second-1 electrode 310, the second dielectric layer 410, and the second-2 electrode 510.

The second-1 electrode pad structure 810 and the second-2 electrode pad structure 860 may be formed on the second-1 interlayer insulating layer 610 and may penetrate through the second-1 interlayer insulating layer 610. The second-1 electrode pad structure 810 may be connected to the second-1 electrode 310, and the second-2 electrode pad structure 860 may be connected to the second-2 electrode 510. The second-1 electrode pad structure 810 and the second-2 electrode pad structure 860 may be later connected to a contact structure, distributing electricity evenly to the second-1 electrode 310 and the second-2 electrode 510.

The second-1 electrode pad structure 810 and the second-2 electrode pad structure 860 may include at least one material among copper (Cu), gold (Au), aluminum (Al), nickel (Ni), palladium (Pd), silver (Ag), titanium (Ti), chromium (Cr), nickel-gold plating (Ni—Au Plating), copper-nickel-palladium plating (Cu—Ni—Pd Plating), and silver-palladium plating (Ag—Pd Plating). However, this is merely exemplary, and the embodiments are not limited to this.

The second-2 interlayer insulating layer 710 may be formed on the second-1 interlayer insulating layer 610, the second-1 electrode pad structure 810, and the second-2 electrode pad structure 860. The second-2 interlayer insulating layer 710 may be a portion that is connected to the first deep trench capacitor DTC_1. The second-2 interlayer insulating layer 710 may be composed of the same material as the first-2 interlayer insulating layer 700.

The second-1 interlayer insulating layer 610 and the second-2 interlayer insulating layer 710 may include at least one material among low-k dielectric materials such as silicon dioxide (SiO₂), silicon nitride (Si₃N₄), polyimide, silicon carbide (SiC), phosphosilicate glass (PSG), borosilicate glass (BSG), and hafnium oxide (HfO₂), and silicon oxynitride (SiON). However, this is merely exemplary, and the embodiments are not limited to this.

The third interlayer insulating layer 900, the fourth interlayer insulating layer 910, the first contact layer 920, and the passivation layer 930 may be formed on at least a portion of the first deep trench capacitor DTC_1 and the second deep trench capacitor DTC_2.

The third interlayer insulating layer 900 may be formed on the epitaxial layer 110E. The third interlayer insulating layer 900 may be formed on the opposite side of the second buffer layer 210 with the epitaxial layer 110E therebetween In other words, the second buffer layer 210 may be formed on at least a portion of the first surface of the epitaxial layer 110E, while the third interlayer insulating layer 900 may be formed on at least a portion of the second surface of the epitaxial layer 110E, which faces the first surface.

The fourth interlayer insulating layer 910 may be formed on the third interlayer insulating layer 900. Furthermore, the fourth interlayer insulating layer 910 may be formed to penetrate through the epitaxial layer 110E and the second buffer layer 210.

The third interlayer insulating layer 900 and the fourth interlayer insulating layer 910 may include at least one material among low-k dielectric materials such as silicon dioxide (SiO₂), silicon nitride (Si₃N₄), polyimide, silicon carbide (SiC), phosphosilicate glass (PSG), borosilicate glass (BSG), and hafnium oxide (HfO₂), and silicon oxynitride (SiON). However, this is merely exemplary, and the embodiments are not limited to this.

The first contact layer 920 may be formed on at least a portion of the fourth interlayer insulating layer 910. Furthermore, the first contact layer 920 may be formed to penetrate through the epitaxial layer 110E, the second buffer layer 210, the second-1 interlayer insulating layer 610, the second-2 interlayer insulating layer 710, and the first-2 interlayer insulating layer 700, making contact with the first-1 electrode pad structure 800 and the first-2 electrode pad structure 850. Further, the first contact layer 920 may be formed to penetrate through the epitaxial layer 110E, the second buffer layer 210, and the second-1 interlayer insulating layer 610, making contact with the second-1 electrode pad structure 810 and the second-2 electrode pad structure 860.

The first contact layer 920 may include at least one material among tungsten (W), titanium (Ti), titanium nitride (TiN), cobalt (Co), nickel (Ni), copper (Cu), molybdenum (Mo), aluminum-copper alloy (AlCu), and palladium (Pd). However, this is merely exemplary, and the embodiments are not limited to this.

The passivation layer 930 may be formed on at least a portion of the fourth interlayer insulating layer 910 and the first contact layer 920. The passivation layer 930 serves to protect the silicon capacitor semiconductor device from external impacts or wear to enhance its physical stability and protects the silicon capacitor semiconductor device from external contamination such as moisture and dust. Moreover, the passivation layer 930 provides electrical insulation between the silicon capacitor semiconductor device and its surroundings, reducing unnecessary electrical interference with its surroundings and ensuring stable operation of the device.

The passivation layer 930 may include at least one material among silicon oxide (SiO₂), silicon nitride (Si₃N₄), polyimide, silicon oxynitride (SiON), aluminum oxide (Al₂O₃), acrylic-based organic insulators, parylene, silicon carbide (SiC), and indium tin oxide (ITO). However, this is merely exemplary, and the embodiments are not limited to this.

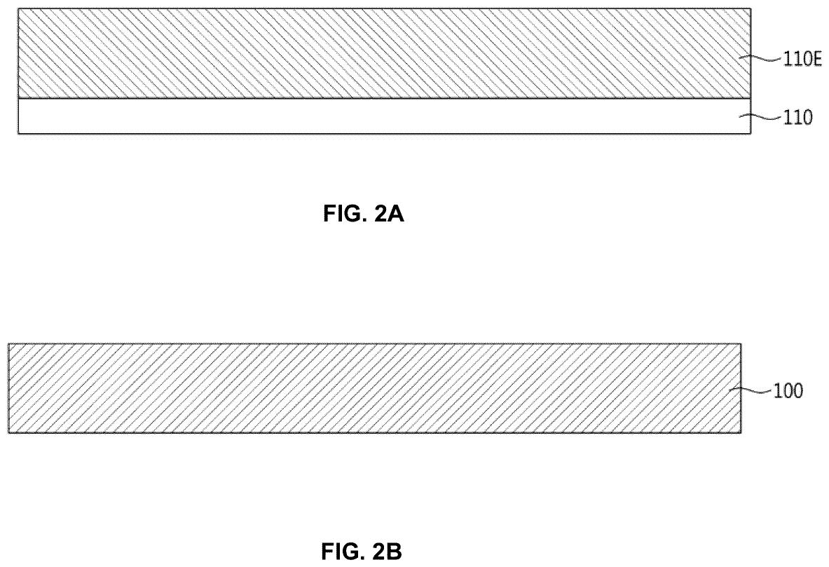

In some embodiments, the silicon capacitor semiconductor device may adopt a shape where the first deep trench capacitor DTC_1 and the second deep trench capacitor DTC_2 are bonded in opposite directions. In this case, the first-2 interlayer insulating layer 700 and the second-2 interlayer insulating layer 710 to which the first deep trench capacitor DTC_1 and the second deep trench capacitor DTC_2 are connected may be made of the same material. As a result, the first deep trench capacitor DTC_1 and the second deep trench capacitor DTC_2 can be bonded the first-2 interlayer insulating layer 700 and the second-2 interlayer insulating layer 710 without the use of additional adhesives. In some embodiments, techniques such as thermal compression bonding, surface activation bonding, chemical-mechanical polishing (CMP) bonding, molecular bonding (direct wafer bonding), or annealing bonding may be used to bond the first deep trench capacitor DTC_1 and the second deep trench capacitor DTC_2 to the first-2 interlayer insulating layer 700 and the second-2 interlayer insulating layer 710 without the use of additional adhesives. The bonding interface (BL) is illustrated to distinguish the first deep trench capacitor DTC_1 and the second deep trench capacitor DTC_2, but in practice, the bonding interface (BL) may not be easily visible. The manufacturing method of the silicon capacitor semiconductor device according to some embodiments of the disclosure will now be described with reference to FIGS. 2A to 11.

FIGS. 2A to 11 illustrate the manufacturing method of a silicon capacitor semiconductor device according to some embodiments of the disclosure.

FIG. 2A depicts the manufacturing process of the second deep trench capacitor DTC_2 is shown, while FIG. 2B depicts the manufacturing process of the first deep trench capacitor DTC_1. The first deep trench capacitor DTC_1 and the second deep trench capacitor DTC_2 may be manufactured through separate processes. However, embodiments are not limited to this, and to shorten process time, after forming the epitaxial layer 110E on the second substrate 110, the remaining processes for the first substrate 100 and the second substrate 110 with the epitaxial layer 110E formed thereon may proceed simultaneously.

Referring to FIG. 2A and FIG. 2B, the second deep trench capacitor DTC_2 may differ from the first deep trench capacitor DTC_1 in that it forms the epitaxial layer 110E on the second substrate 110. In other words, while the first deep trench capacitor DTC_1 forms the capacitor structure by creating deep trenches within the first substrate 100, the second deep trench capacitor DTC_2 forms the capacitor structure by forming the epitaxial layer 110E on the second substrate 110 and then creating deep trenches within the epitaxial layer 110E.

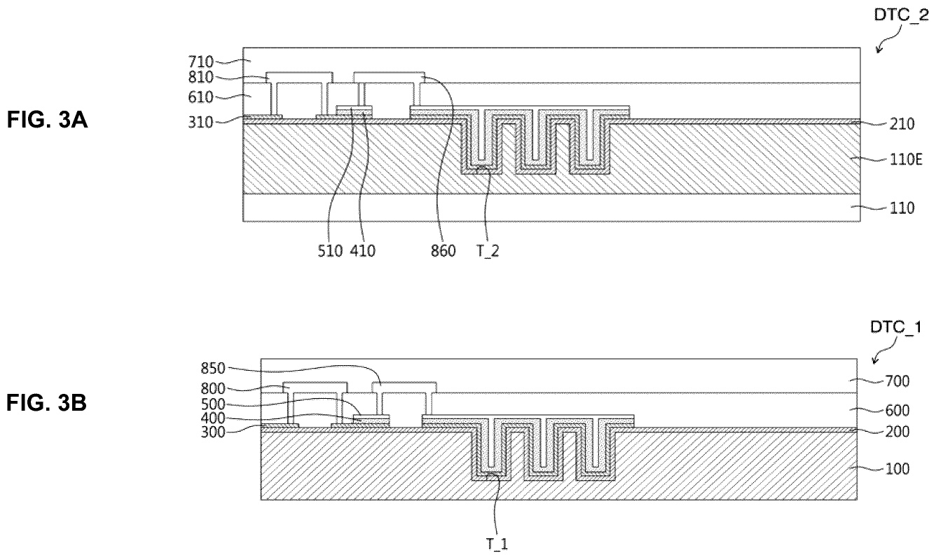

Similarly, FIG. 3A depicts the manufacturing process of the second deep trench capacitor DTC_2, and FIG. 3B depicts the manufacturing process of the first deep trench capacitor DTC_1.

Referring to FIG. 3B, a first trench T_1 may be formed within the first substrate 100. Then, a first buffer layer 200 may be conformally formed along the profile of the first substrate 100 and the first trench T_1. Conformally forming the first buffer layer 200 along the profile of the first substrate 100 and the first trench T_1 means that the first buffer layer 200 is formed to uniformly cover the surface of the first substrate 100 and the first trench T_1. In other words, the first buffer layer 200 may be formed with a uniform thickness along the surface of the first substrate 100 where the first trench T_1 is formed. Here, “uniform” does not imply being physically identical but rather being “substantially the same” considering tolerances in semiconductor processes.

Subsequently, the first-1 electrode 300 may be formed on at least a portion of the first buffer layer 200. The pattern of the first-1 electrode 300 can be formed in various ways. For example, the first-1 electrode 300 may be conformally formed on the first buffer layer 200, and then a portion of the first-1 electrode 300 may be etched to expose at least a portion of the first buffer layer 200, thereby forming the pattern of the first-1 electrode 300. Alternatively, a portion of the first buffer layer 200 may be masked, and the first-1 electrode 300 may be conformally formed on both the first buffer layer 200 and the mask. The mask may then be removed to form the pattern of the first-1 electrode 300. The embodiments of the present disclosure are not limited to the process of forming the pattern of the first-1 electrode 300, and those skilled in the art can form the pattern of the first-1 electrode 300 in various ways.

The dielectric layer 400 may be formed on at least a portion of the first-1 electrode 300. Similarly, the pattern of the dielectric layer 400 can be formed in various ways, and the embodiments are not limited to specific methods of pattern formation.

Next, the first-2 electrode 500 may be formed on the first dielectric layer 400. The pattern of the first-2 electrode 500 can also be formed in various ways, and the embodiments are not limited to specific methods of pattern formation.

Subsequently, the first-1 interlayer insulating layer 600 may be formed to cover the first substrate 100, the first buffer layer 200, the first-1 electrode 300, the dielectric layer 400, and the first-2 electrode 500.

A portion of the first-1 interlayer insulating layer 600 may be removed to form the first-1 electrode pad structure 800 so as to be connected to the first-1 electrode 300. Similarly, a portion of the first-1 interlayer insulating layer 600 may be removed to form the first-2 electrode pad structure 850 so as to be connected to the first-2 electrode 500.

Next, the first-2 interlayer insulating layer 700 may be formed to cover the first substrate 100, the first buffer layer 200, the first-1 electrode 300, the dielectric layer 400, the first-2 electrode 500, the first-1 electrode pad structure 800, and the first-2 electrode pad structure 850.

Referring to FIG. 3A, a second trench T_2 may be formed within the epitaxial layer 110E on the second substrate 110. Then, a second buffer layer 210 may be conformally formed along the profile of the epitaxial layer 110E and the second trench T_2.

Next, the second-1 electrode 310 may be formed on at least a portion of the second buffer layer 210. The pattern of the second-1 electrode 310 can be formed in various ways, and the embodiments are not limited to specific methods of pattern formation.

The second dielectric layer 410 may be formed on at least a portion of the second-1 electrode 310. Similarly, the pattern of the dielectric layer 410 can be formed in various ways, and the embodiments are not limited to specific methods of pattern formation.

The second-2 electrode 510 may be formed on the second dielectric layer 410. The pattern of the second-2 electrode 510 can also be formed in various ways, and the embodiments are not limited to specific methods of pattern formation.

The second-1 interlayer insulating layer 610 may be formed to cover the epitaxial layer 110E, the second buffer layer 210, the second-1 electrode 310, the dielectric layer 410, and the second-2 electrode 510.

A portion of the second-1 interlayer insulating layer 610 may be removed to form the second-1 electrode pad structure 810 so as to be connected to the second-1 electrode 310. Similarly, a portion of the second-1 interlayer insulating layer 610 may be removed to form the second-2 electrode pad structure 860 so as to be connected to the second-2 electrode 510.

Next, the second-2 interlayer insulating layer 710 may be formed to cover the epitaxial layer 110E, the second buffer layer 210, the second-1 electrode 310, the dielectric layer 410, the second-2 electrode 510, the second-1 electrode pad structure 810, and the second-2 electrode pad structure 860.

Through the above process, the first deep trench capacitor DTC_1 and the second deep trench capacitor DTC_2 can be formed. As can be seen above, the manufacturing process for the first deep trench capacitor DTC_1 and the second deep trench capacitor DTC_2 differs only in whether the first trench T_1 is formed in the first substrate 100 or the second trench T_2 is formed in the epitaxial layer 110E, and the remaining processes are substantially the same.

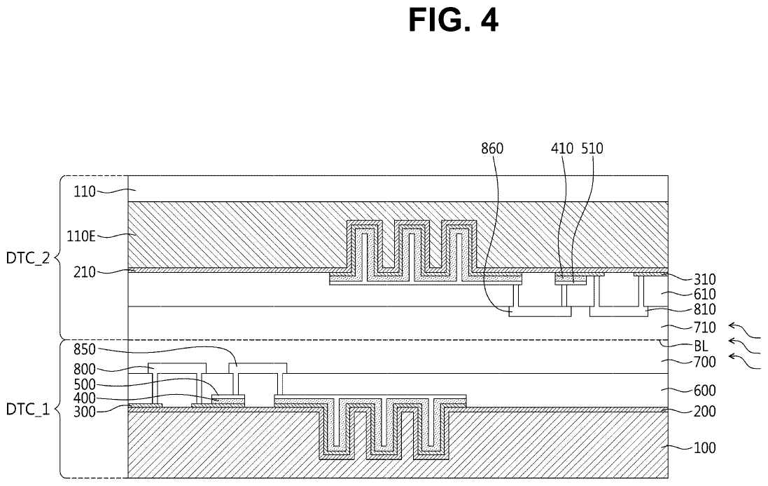

Referring to FIG. 4, the first deep trench capacitor DTC_1 and the second deep trench capacitor DTC_2 may be bonded together. Specifically, the first-2 interlayer insulating layer 700 of the first deep trench capacitor DTC_1 and the second-2 interlayer insulating layer 710 of the second deep trench capacitor DTC_2 may be bonded. As described above, since the first-2 interlayer insulating layer 700 and the second-2 interlayer insulating layer 710 are composed of the same material, bonding methods such as thermal compression bonding, surface activation bonding, chemical mechanical polishing (CMP) bonding, direct wafer bonding, or annealing bonding may be used to bond the first-2 interlayer insulating layer 700 and the second-2 interlayer insulating layer 710.

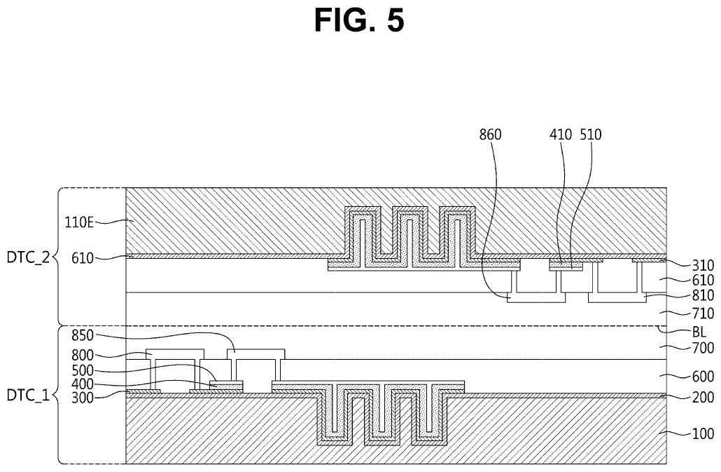

Referring to FIG. 5, after bonding the first deep trench capacitor DTC_1 and the second deep trench capacitor DTC_2, the second substrate 110 may be removed. In some embodiments, the second substrate 110 and the epitaxial layer 110E, which are composed of the same material, may differ in terms of the material's purity. Therefore, the second substrate 110 can be removed using an etching process with an appropriate selectivity ratio. In some embodiments, the second substrate 110 may first undergo a back-grinding process, followed by wet etching and chemical mechanical polishing (CMP) with an appropriate selectivity ratio to remove the second substrate 110. However, the embodiments are not limited to this.

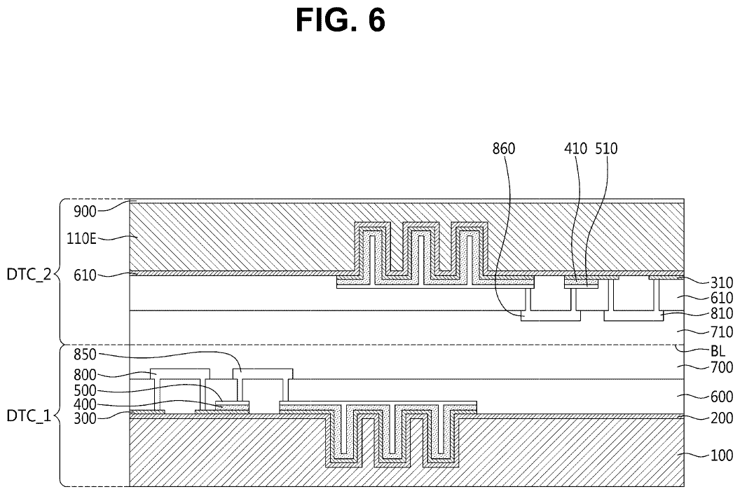

Referring to FIG. 6, the third interlayer insulating layer 900 may be conformally formed on the epitaxial layer 110E. In other words, the third interlayer insulating layer 900 may be formed on the exposed epitaxial layer 110E to protect the epitaxial layer 110E exposed due to the removal of the second substrate 110.

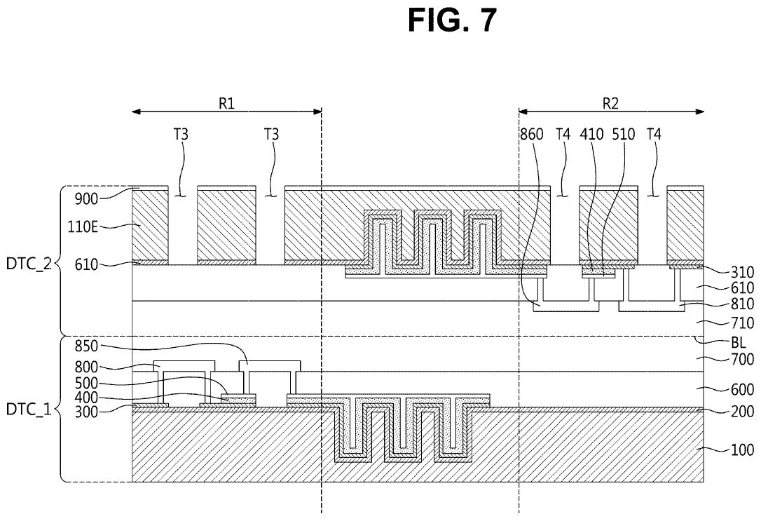

Referring to FIG. 7, for the sake of explanation, the overlapping area of the first-1 electrode pad structure 800 and the first-2 electrode pad structure 850 is defined as a first region R1, while the overlapping area of the second-1 electrode pad structure 810 and the second-2 electrode pad structure 860 is defined as a second region R2.

A third trench T3 may be formed in the first region R1, and a fourth trench T4 may be formed in the second region R2. Specifically, the third trench T3 may be formed by removing at least a portion of the third interlayer insulating layer 900, the epitaxial layer 110E, and the second buffer layer 210 in the first region R1. Similarly, the fourth trench T4 may be formed by removing at least a portion of the third interlayer insulating layer 900, the epitaxial layer 110E, and the second buffer layer 210 in the second region R2. The formation of the third trench T3 and the fourth trench T4 may involve various processes. For example, a mask may be formed on the third interlayer insulating layer 900 using a photoresist according to the pattern of the third trench T3 and the fourth trench T4. An etching process may then be performed to etch at least a portion of the third interlayer insulating layer 900, the epitaxial layer 110E, and the second buffer layer 210, thereby forming the third trench T3 and the fourth trench T4. The mask used for forming the third trench T3 and the fourth trench T4 may be removed later. However, this is merely exemplary, and the embodiments are not limited to this.

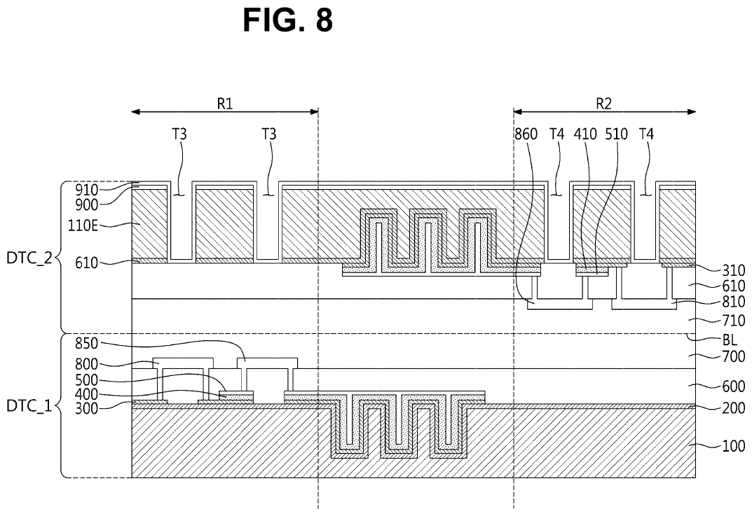

Referring to FIG. 8, the fourth interlayer insulating layer 910 may be conformally formed on the third interlayer insulating layer 900, the third trench T3, and the fourth trench T4. In other words, the fourth interlayer insulating layer 910 may be conformally formed along the surface shape of the third interlayer insulating layer 900, the third trench T3, and the fourth trench T4.

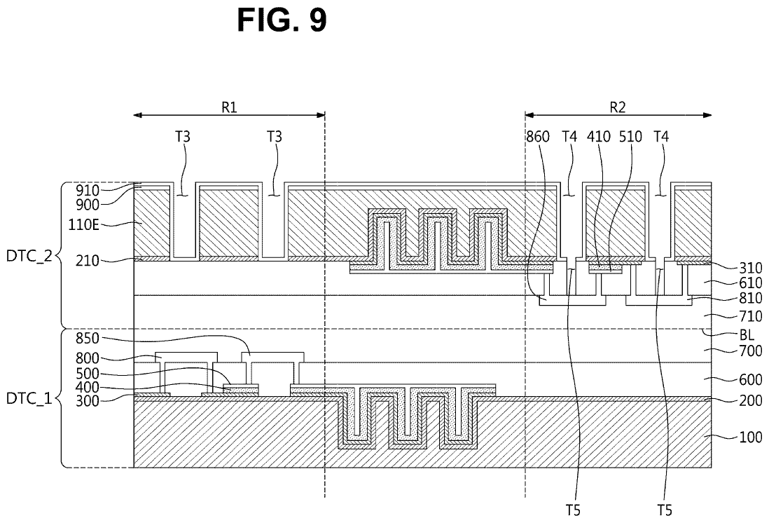

Referring to FIG. 9, a fifth trench T5 may be formed in the second region R2. Specifically, the fifth trench T5 may be formed by removing at least a portion of the fourth interlayer insulating layer 910 and the second-1 interlayer insulating layer 610 to expose at least a portion of the second-1 electrode pad structure 810 and the second-2 electrode pad structure 860. Similarly, the fifth trench T5 may be formed using various processes. For example, a photoresist may be applied to the fourth interlayer insulating layer 910 to create a mask according to the pattern of the fifth trench T5 in the second region R2. An etching process may then be performed to remove at least a portion of the fourth interlayer insulating layer 910 and the second-1 interlayer insulating layer 610, thereby forming the fifth trench T5 exposing at least a portion of the second-1 electrode pad structure 810 and the second-2 electrode pad structure 860. The mask used for forming the fifth trench T5 may be removed later. However, this is merely exemplary, and the embodiments are not limited to this.

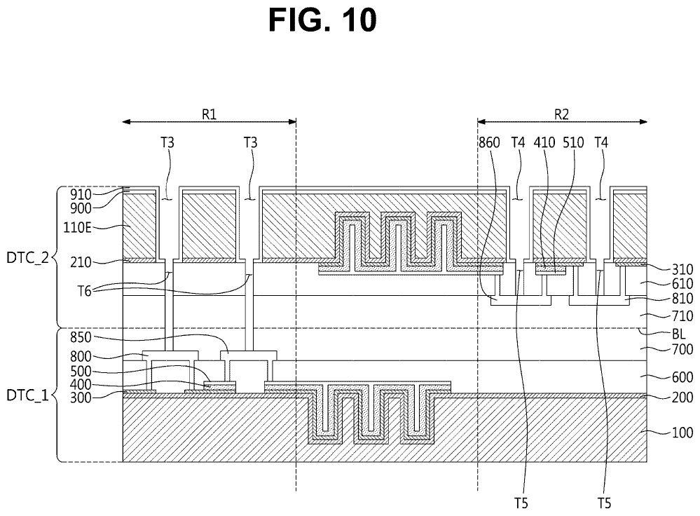

Referring to FIG. 10, a sixth trench T6 may be formed in the first region R1. Specifically, the sixth trench T6 may be formed by removing at least a portion of the fourth interlayer insulating layer 910, the second-1 interlayer insulating layer 610, the second-2 interlayer insulating layer 710, and the first-2 interlayer insulating layer 700, exposing at least a portion of the first-1 electrode pad structure 800 and the first-2 electrode pad structure 850 in the first region R1. The sixth trench T6 can also be formed using various processes. For instance, a photoresist may be applied in the state shown in FIG. 9, and a mask may be formed according to the pattern of the sixth trench T6 in the first region R1. Subsequently, an etching process may be performed to remove at least a portion of the fourth interlayer insulating layer 910, the second-1 interlayer insulating layer 610, the second-2 interlayer insulating layer 710, and the first-2 interlayer insulating layer 700, thereby forming the sixth trench T6 exposing at least a portion of the first-1 electrode pad structure 800 and the first-2 electrode pad structure 850. The mask used for forming the sixth trench T6 may be removed later. However, this is merely exemplary, and the embodiments are not limited to this.

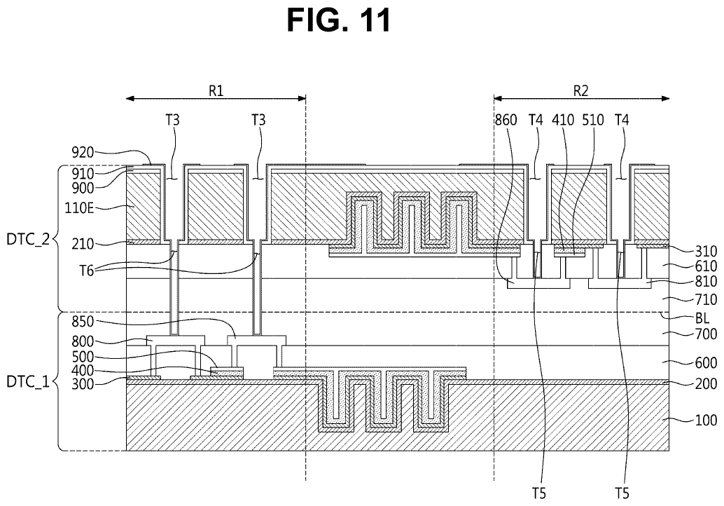

Referring to FIG. 11, a first contact layer 920 may be formed to contact the first-1 electrode pad structure 800, the first-2 electrode pad structure 850, the second-1 electrode pad structure 810, and the fourth electrode pad structure 860. More specifically, the first contact layer 920 may be formed to fill at least a portion of the fifth trench T5 and the sixth trench T6, thereby contacting the first-1 electrode pad structure 800, the first-2 electrode pad structure 850, the second-1 electrode pad structure 810, and the second-2 electrode pad structure 860.

Referring again to FIG. 1, the passivation layer 930 may be formed to expose at least a portion of the first contact layer 920. The passivation layer 930 serves to protect the remaining portions other than the exposed portion of the first contact layer 920. Voltage may be applied to the exposed portion of the first contact layer 920 later.

According to some embodiments of the present disclosure, the silicon capacitor semiconductor device may include both the first deep trench capacitor DTC_1 and the second deep trench capacitor DTC_2. When an appropriate voltage is applied to the first contact layer 920, the first deep trench capacitor DTC_1 and the second deep trench capacitor DTC_2 may form a parallel connection structure, thereby achieving high-capacity capacitance in the silicon capacitor semiconductor device. Furthermore, according to some embodiments of the present disclosure, since the manufacturing processes for the first deep trench capacitor DTC_1 and the second deep trench capacitor DTC_2 are mostly shared, this is advantageous for mass production.

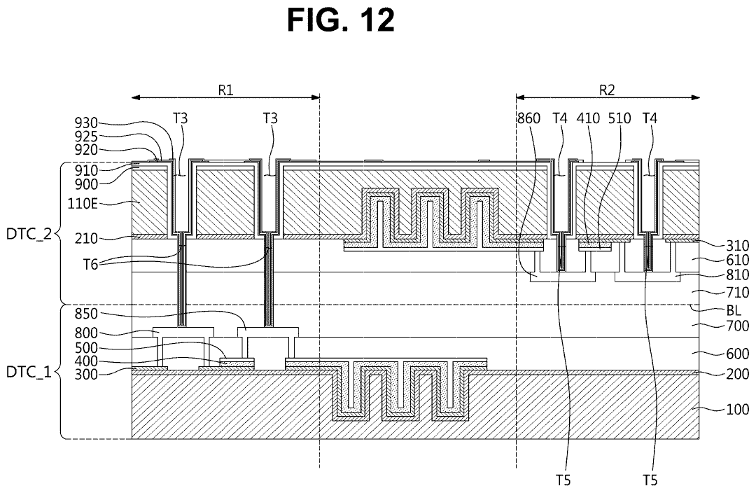

FIG. 12 illustrates a cross-sectional view of a silicon capacitor semiconductor device according to other embodiments of the present disclosure. For simplicity, descriptions identical or similar to those previously provided are omitted or briefly explained.

Referring to FIG. 12, the contact structure of the silicon capacitor semiconductor device may be implemented with multiple layers. Specifically, according to some embodiments of the present disclosure, the silicon capacitor semiconductor device may include a second contact layer 925 formed on the first contact layer 920. The first contact layer 920 and the second contact layer 925 may include different materials or, even if the materials are the same, they may differ in composition ratios. Implementing a multi-layered contact structure in the silicon capacitor semiconductor device can help reduce contact resistance and enhance stability. Those skilled in the art can introduce various contact structures as needed. For instance, the first contact layer 920 may include at least one material among tungsten (W), titanium (Ti), or titanium nitride (TiN), and the second contact layer 925 may include at least one material among titanium (Ti), titanium nitride (TiN), or aluminum-copper alloy (AlCu).

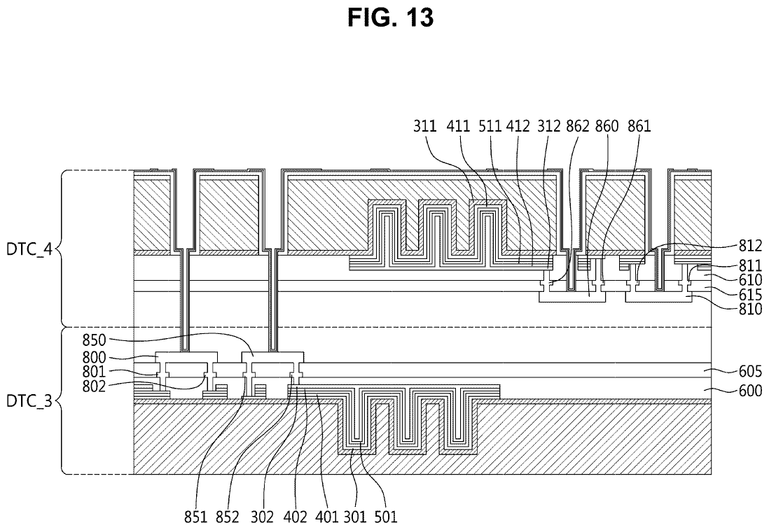

FIG. 13 illustrates a cross-sectional view of a silicon capacitor semiconductor device according to other embodiments of the present disclosure. For simplicity, descriptions identical or similar to those previously provided are omitted or briefly explained.

Referring to FIG. 13, the silicon capacitor semiconductor device may include a third deep trench capacitor DTC_3 and a fourth deep trench capacitor DTC_4. The third deep trench capacitor DTC_3 may include a first-3 electrode 301, a first-1 dielectric layer 401, a first-4 electrode 501, a first-2 dielectric layer 402, and a first-5 electrode 302 on the first buffer layer 200. Similarly, the fourth deep trench capacitor DTC_4 may include a second-3 electrode, a second-1 dielectric layer 411, a second-4 electrode 511, a second-2 dielectric layer 412, and a second-5 electrode 312 on the second buffer layer 210. Unlike the silicon capacitor semiconductor device in FIG. 1, which includes a pair of electrodes and a single dielectric layer formed between the electrodes, the silicon capacitor semiconductor device according to some embodiments of the present disclosure may include three layers of electrodes and two dielectric layers formed between the electrodes. However, this is merely exemplary, and the embodiments are not limited to the number of electrodes. For instance, those skilled in the art can implement a silicon capacitor semiconductor device with four layers of electrodes and three dielectric layers between the electrodes without departing from the scope of the present disclosure.

In other words, silicon capacitor semiconductor devices according to some embodiments of the present disclosure may include deep trench capacitors with three or more electrode layers and multiple dielectric layers arranged between the electrodes.

However, designing deep trench capacitors with three or more electrode layers and multiple dielectric layers arranged between the electrodes may require certain structural modifications. For instance, the first-1 electrode pad structure 800 may further include a first sub-pad 801 and a second sub-pad 802 according to the addition of electrodes. Similarly, the first-2 electrode pad structure 850 may include a third sub-pad 851 and a fourth sub-pad 852 according to the addition of electrodes. Likewise, the second-1 electrode pad structure 810 may include a fifth sub-pad 811 and a sixth sub-pad 812 according to the addition of electrodes. In addition, the second-2 electrode pad structure 860 may include a seventh sub-pad 861 and an eighth sub-pad 862 according to the addition of electrodes.

Further, a first sub-interlayer insulating layer 605 may be formed on the first-1 interlayer insulating layer 600 in order to form the first sub-pad 801 to the fourth sub-pad 852. Similarly, a second sub-interlayer insulating layer 615 may be formed on the second-1 interlayer insulating layer 610 in order to form the fifth sub-pad 811 to the eighth sub-pad 862. In other words, the first-1 electrode pad structure 800 and the first-2 electrode pad structure 850 may pass through the first-1 interlayer insulating layer 600 and the first sub-interlayer insulating layer 605 and be connected to the first-3 electrode 301, the first-4 electrode 501, and the first-5 electrode 302. Likewise, the second-1 electrode pad structure 810 and the fourth electrode pad structure 860 may pass through the second-1 interlayer insulating layer 610 and the second sub-interlayer insulating layer 615 and be connected to the second-3 electrode 311, the second-4 electrode 511, and the second-5 electrode 312.

What is claimed is:

1. A silicon capacitor semiconductor device comprising:
a first substrate;
an epitaxial layer grown from the same material as that of the first substrate;
a first buffer layer formed along a profile of a first trench formed in the first substrate;
a first capacitor structure on the first buffer layer;
a first interlayer insulating layer on the first capacitor structure;
a second buffer layer formed along a profile of a second trench formed in the epitaxial layer;
a second capacitor structure on the second buffer layer; and
a second interlayer insulating layer between the first interlayer insulating layer and the second capacitor structure.

2. The silicon capacitor semiconductor device of claim 1, wherein:
the first capacitor structure comprises a first-1 electrode, a first dielectric layer on the first-1 electrode, and a first-2 electrode on the first dielectric layer, and
the second capacitor structure comprises a second-1 electrode, a second dielectric layer on the second-1 electrode, and a second-2 electrode on the second dielectric layer.

3. The silicon capacitor semiconductor device of claim 2, further comprising:
a first-1 electrode pad structure connected to the first-1 electrode and passing through at least a portion of the first interlayer insulating layer;
a first-2 electrode pad structure connected to the first-2 electrode and passing through at least a portion of the first interlayer insulating layer;
a second-1 electrode pad structure connected to the second-1 electrode and passing through at least a portion of the second interlayer insulating layer; and
a second-2 electrode pad structure connected to the second-2 electrode and passing through at least a portion of the second interlayer insulating layer.

4. The silicon capacitor semiconductor device of claim 3, further comprising a contact layer passing through at least a portion of the epitaxial layer, the second buffer layer, the second interlayer insulating layer, or the first interlayer insulating layer.

5. The silicon capacitor semiconductor device of claim 4, further comprising:
a third interlayer insulating layer formed between the contact layer and the epitaxial layer; and
a passivation layer on the contact layer.

6. The silicon capacitor semiconductor device of claim 4, wherein the contact layer comprises multiple layers.

7. The silicon capacitor semiconductor device of claim 1, wherein:
the first interlayer insulating layer comprises a first-1 interlayer insulating layer and a first-2 interlayer insulating layer on the first-1 interlayer insulating layer;
the second interlayer insulating layer comprises a second-1 interlayer insulating layer and a second-2 interlayer insulating layer on the second-1 interlayer insulating layer; and
the first-2 interlayer insulating layer and the second-2 interlayer insulating layer are made of the same material.

8. The silicon capacitor semiconductor device of claim 7, wherein the first-2 interlayer insulating layer and the second-2 interlayer insulating layer are in direct contact with each other.

9. The silicon capacitor semiconductor device of claim 1, wherein the first and second buffer layers each comprise at least one of silicon dioxide (SiO2), phosphosilicate glass (PSG), borosilicate glass (BSG), borosilicate phosphosilicate glass (BPSG), silicon nitride (Si3N4), silicon oxynitride (SiON), or hafnium oxide (HfO2).

10. The silicon capacitor semiconductor device of claim 1, wherein the first and second interlayer insulating layers each comprise at least one of silicon oxide (SiO2), silicon nitride (Si3N4), polyimide, silicon carbide (SiC), phosphosilicate glass (PSG), borosilicate glass (BSG), hafnium oxide (HfO2), or silicon oxynitride (SiON).

11. A method for manufacturing a silicon capacitor semiconductor device comprising:
forming a first trench in a first substrate, forming a first buffer layer, a first-1 electrode, a first dielectric layer, and a first-2 electrode on at least a portion of the first trench, forming a first-1 interlayer insulating layer on the first-2 electrode, forming a first-1 electrode pad structure and a first-2 electrode pad structure that penetrate the first-1 interlayer insulating layer, and forming a first-2 interlayer insulating layer covering the first-1 electrode pad structure and the first-2 electrode pad structure;
forming an epitaxial layer on a second substrate different from the first substrate, the epitaxial layer being made of the same material as the second substrate, forming a second trench in the epitaxial layer, forming a second buffer layer, a second-1 electrode, a second dielectric layer, and a second-2 electrode on at least a portion of the second trench, forming a second-1 interlayer insulating layer on the second-2 electrode, forming a second-1 electrode pad structure and a second-2 electrode pad structure that penetrate the second-1 interlayer insulating layer, and forming a second-2 interlayer insulating layer covering the second-1 electrode pad structure and the second-2 electrode pad structure;
bonding the first-2 interlayer insulating layer and the second-2 interlayer insulating layer using at least one of thermal compression bonding, surface activation bonding, chemical mechanical polishing (CMP) bonding, direct wafer bonding, or annealing bonding; and
removing the second substrate using a selectivity ratio between the second substrate and the epitaxial layer.

12. The method for manufacturing the silicon capacitor semiconductor device according to claim 11, further comprising forming a contact structure connected to the first-1 electrode pad structure, the first-2 electrode pad structure, the second-1 electrode pad structure, and the second-2 electrode pad structure.

13. The method for manufacturing the silicon capacitor semiconductor device according to claim 12, further comprising conformally forming a third interlayer insulating layer on the epitaxial layer.

14. The method for manufacturing the silicon capacitor semiconductor device according to claim 12, wherein forming the contact structure comprises:
removing at least a portion of the epitaxial layer, the second buffer layer, or the second-1 interlayer insulating layer to expose the second-1 electrode pad structure and the second-2 electrode pad structure;
removing at least a portion of the epitaxial layer, the second buffer layer, the second-1 interlayer insulating layer, the second-2 interlayer insulating layer, or the first-2 interlayer insulating layer to expose the first-1 electrode pad structure and the first-2 electrode pad structure; and
forming the contact structure to contact the first-1 electrode pad structure, the first-2 electrode pad structure, the second-1 electrode pad structure, and the second-2 electrode pad structure.

15. A silicon capacitor semiconductor device comprising:
a first substrate with a first trench;
a first capacitor structure on the first trench, the first capacitor structure including a first-1 electrode layer on the first trench, a first-1 dielectric layer on the first-1 electrode layer, a first-2 electrode layer on the first-1 dielectric layer, a first-2 dielectric layer on the first-2 electrode layer, and a first-3 electrode layer on the first-2 dielectric layer;
an epitaxial layer with a second trench, the epitaxial layer being formed by an epitaxy process;
a second capacitor structure on the second trench, the second capacitor structure including a second-1 electrode layer on the second trench, a second-1 dielectric layer on the second-1 electrode layer, a second-2 electrode layer on the second-1 dielectric layer, a second-2 dielectric layer on the second-2 electrode layer, and a second-3 electrode layer on the second-2 dielectric layer;
a first interlayer insulating layer on the first capacitor structure; and
a second interlayer insulating layer on the second capacitor structure, wherein at least portions of the first interlayer insulating layer and the second interlayer insulating layer are in direct contact with each other.

16. The silicon capacitor semiconductor device according to claim 15, further comprising:
a first electrode pad structure connected to the first capacitor structure; and
a second electrode pad structure connected to the second capacitor structure.

17. The silicon capacitor semiconductor device according to claim 16, further comprising:
a contact structure that penetrates at least a portion of the first interlayer insulating layer and the second interlayer insulating layer to be connected to the first electrode pad structure and penetrates at least a portion of the second interlayer insulating film to be connected to the second electrode pad structure.

18. The silicon capacitor semiconductor device according to claim 17, wherein the contact structure comprises a first contact layer directly contacting the first electrode pad structure and the second electrode pad structure and a passivation layer on the first contact layer.

19. The silicon capacitor semiconductor device according to claim 17, wherein the contact structure comprises a first contact layer directly contacting the first electrode pad structure and the second electrode pad structure, a second contact layer on the first contact layer, the second contact layer being made of a different material or having a different composition ratio than the first contact layer, and a passivation layer on the second contact layer.

20. The silicon capacitor semiconductor device according to claim 15, wherein:
the first interlayer insulating layer comprises a first-1 interlayer insulating layer and a first-2 interlayer insulating layer on the first-1 interlayer insulating layer,
the second interlayer insulating layer comprises a second-1 interlayer insulating layer and a second-2 interlayer insulating layer on the second-1 interlayer insulating layer, and
the first-2 interlayer insulating layer and the second-2 interlayer insulating layer are made of the same material.
